(19) United States
(12) Patent Application Publication
(10) Pub. No.: US 2025/0379075 A1
(43) Pub. Date: Dec. 11, 2025

(54) HIGH-THROUGHPUT LOAD LOCK CHAMBER

(71) Applicant: ASML Netherlands B.V., Veldhoven (NL)

(72) Inventors: Dongchi YU, San Jose, CA (US); Yi-Chen LIN, San Jose, CA (US); Jun-li LIN, San Jose, CA (US); Shao-Wei FU, San Jose, CA (US)

(73) Assignee: ASML Netherlands B.V., Veldhoven (NL)

(21) Appl. No.: 18/874,533

(22) PCT Filed: Jul. 26, 2023
(86) PCT No.: PCT/EP2023/070790

§ 371 Date: Dec. 12, 2024

Related U.S. Application Data
(60) Provisional application No. 63/395,754, filed on Aug. 5, 2022.

(51) Int. Cl. H01L 21/67

(52) U.S. Cl. CPC H01L 21/67201; H01L 21/67213

(57) ABSTRACT

An improved load lock chamber is provided. The load lock chamber includes a gas vent port, a first compartment configured to receive a wafer for loading into and unloading from a main vacuum chamber, and a second compartment partitioned from the first compartment. The second compartment is configured to receive gas through the gas vent port. The load lock chamber also includes a flow attenuation path connecting the first compartment and the second compartment. The flow attenuation path is configured to route the gas from the second compartment to the first compartment and to attenuate gas flow.

### CROSS-REFERENCE TO RELATED APPLICATIONS

This application claims priority of U.S. application 63/395,754 which was filed on Aug. 5, 2022 and which is incorporated herein in its entirety by reference.

### FIELD

The embodiments provided herein disclose a particle beam inspection apparatus, and more particularly, a particle beam inspection apparatus including an improved load lock chamber.

### BACKGROUND

When manufacturing semiconductor integrated circuit (IC) chips, pattern defects and/or uninvited particles (residuals) inevitably appear on a wafer and/or a mask during fabrication processes, thereby reducing the yield to a great degree. For example, uninvited particles may be troublesome for patterns with smaller critical feature dimensions, which have been adopted to meet the increasingly more advanced performance requirements of IC chips.

Pattern inspection tools with a charged particle beam have been used to detect the defects or uninvited particles. These tools typically employ a scanning electron microscope (SEM). In the SEM, a beam of primary electrons having a relatively high energy is decelerated to land on a sample at a relatively low landing energy and is focused to form a probe spot thereon. Due to this focused probe spot of primary electrons, secondary electrons will be generated from the surface. By scanning the probe spot over the sample surface and collecting the secondary electrons, pattern inspection tools may obtain an image of the sample surface.

During operation of an inspection tool, the wafer is typically held by a wafer stage in a main chamber. The inspection tool may comprise a wafer positioning device for positioning the wafer stage and wafer relative to the e-beam. This may be used to position a target area on the wafer, i.e., an area to be inspected, in an operating range of the e-beam. During inspection, the main chamber is maintained in a deep vacuum state. The inspection tool may also comprise a small vacuum chamber called a load lock chamber, which is connected to the large main chamber. The load lock chamber is used to transfer wafers between the atmospheric cleanroom environment and the main chamber in a deep vacuum state.

### SUMMARY

The embodiments provided herein disclose a charged-particle beam apparatus, and more particularly improved systems and methods for signal electron detection.

One aspect of the present disclosure is directed to a load lock chamber comprising a gas vent port, a first compartment configured to receive a wafer for loading into and unloading from a main vacuum chamber, and a second compartment partitioned from the first compartment. The second compartment may be configured to receive gas through the gas vent port. The load lock chamber may also include a flow attenuation path connecting the first compartment and the second compartment, the flow attenuation path configured to route the gas from the second compartment to the first compartment and to attenuate gas flow.

Another aspect of the present disclosure is directed to a load lock assembly comprising a load lock chamber, a vacuum pump connected to the load lock chamber, and a gas supply connected to the load lock chamber through a gas vent port. The load lock chamber comprises the gas vent port, a first compartment configured to receive a wafer for loading into and unloading from a main vacuum chamber, and a second compartment partitioned from the first compartment. The second compartment may be configured to receive gas through the gas vent port. The load lock chamber may also include a flow attenuation path connecting the first compartment and the second compartment, the flow attenuation path configured to route the gas from the second compartment to the first compartment and to attenuate gas flow.

Other advantages of the present invention will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1A is a schematic diagram illustrating an exemplary charged particle beam inspection system, consistent with embodiments of the present disclosure.

FIG. 1B is a schematic diagram illustrating an exemplary wafer loading sequence in the charged particle beam inspection system of FIG. 1A, consistent with embodiments of the present disclosure.

FIG. 2A is a schematic diagram illustrating an exemplary charged particle beam inspection system with a conventional load lock chamber.

FIG. 2B is a schematic diagram illustrating a conventional load lock chamber, such as the load lock chamber included in the exemplary charged particle beam inspection system shown in FIG. 2A.

FIG. 2C is an illustration showing a technician performing maintenance work under the load lock chamber shown in FIGS. 2A and 2B.

FIG. 3A is a schematic diagram illustrating an exemplary load lock chamber, consistent with embodiments of the present disclosure.

FIG. 3B is a schematic diagram illustrating the sectional view of the exemplary load lock chamber shown in FIG. 3A, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smartphone can be as small as a thumbnail and yet may include over 10 billion transistors, the size of each transistor being less than 1/1000th the size of a human hair.

Making these ICs with so many extremely small transistors is a complex, time-consuming, and expensive process, often involving hundreds of individual manufacturing steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection can be carried out using a scanning electron microscope (SEM). An SEM can be used to create the images of these extremely small structures, in effect, taking a “picture” of the structures. The images can be used to determine if the structure was formed properly and also if it was formed in the proper location. If the structure is defective, then the process can be adjusted so the defect is less likely to occur again.

While high process yield is desirable in an IC chip manufacturing facility, it is also essential to maintain a high wafer throughput, defined as the number of wafers processed per hour. High process yields and high wafer throughput can be impacted by the presence of defects, especially when those defects necessitate an operator intervention for a closer review. Thus, high throughput detection and identification of micro and nano-sized defects by inspection tools (such as an SEM) is essential for maintaining high yields and low cost.

One aspect of the present disclosure includes an improved load lock system that increases the throughput of the overall inspection system. The improved load lock system prepares a wafer in a manner that speeds up the inspection process and reduces the chance of introducing an uninvited particle, when compared to conventional particle beam inspection systems.

For example, during operation of an inspection tool, the wafer is typically held by a wafer stage in a main chamber. The main chamber is maintained in a deep vacuum state to allow the particle beams, such as electrons, to travel within the main chamber unimpeded, and to prevent electrical discharge in the gun assembly (e.g., arcing). The inspection tool may also comprise a small vacuum chamber called a load lock chamber, which is connected to the large main chamber. The load lock chamber is used to transfer wafers between the atmospheric cleanroom environment and the main chamber in a deep vacuum state. To transfer a wafer into the main chamber for inspection, the wafer is first placed in the load lock chamber, which is then depressurized to match the vacuum level of the main chamber. After inspection, the wafer is again placed in the load lock chamber, and a venting operation is performed to restore the pressure of the load lock chamber to an atmospheric level.

In a conventional inspection system, the venting structures (e.g., a gas supply, a gas vent valve, a gas vent diffuser, etc.) are placed on top of the load lock chamber to provide a strong downward gas venting flow within the load lock chamber. Accordingly, the pumping-down structures (e.g., vacuum pumps, a plasma cleaner, a residual gas analyzer, etc.) are placed underneath of the load lock chamber. The pumping-down structures are typically complex, heavy, and more prone for malfunctioning. However, the tight space under the load lock chamber creates substantial difficulties for installing, troubleshooting, or fixing the pumping-down structures.

The improved load lock chamber has a redesigned internal structure that allows positioning the gas vent ports on the side or the bottom of the load lock chamber, while still being capable of providing the desired downward gas venting flow within the load lock chamber. The improved load lock chamber further allows relocating the pump-down structure to a place for better access and convenient maintenance work.

Relative dimensions of components in drawings may be exaggerated for clarity. Within the following description of drawings the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

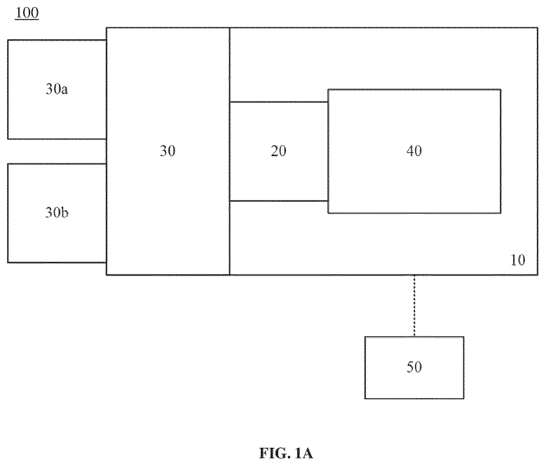

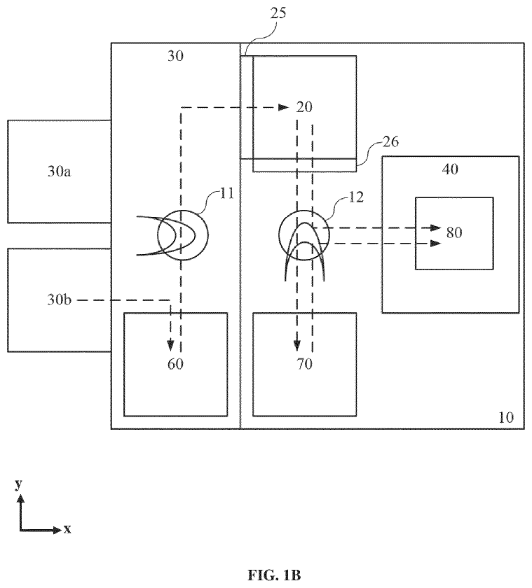

Reference is now made to FIG. 1A, which is a schematic diagram illustrating an exemplary charged particle beam inspection system 100, consistent with embodiments of the present disclosure. As shown in FIG. 1A, charged particle beam inspection system 100 includes a main chamber 10, a load lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present invention to specific charged particles. It is further appreciated that electron beam tool 40 can be a single-beam tool that utilizes a single electron beam or a multi-beam tool that utilizes multiple electron beams.

EFEM 30 includes a first loading port 30a and a second loading port 30b. EFEM 30 may include additional loading port(s). First loading port 30a and second loading port 30b may, for example, receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (e.g., the robotic arms shown in FIG. 1B) in EFEM 30 transport the wafers to load lock chamber 20.

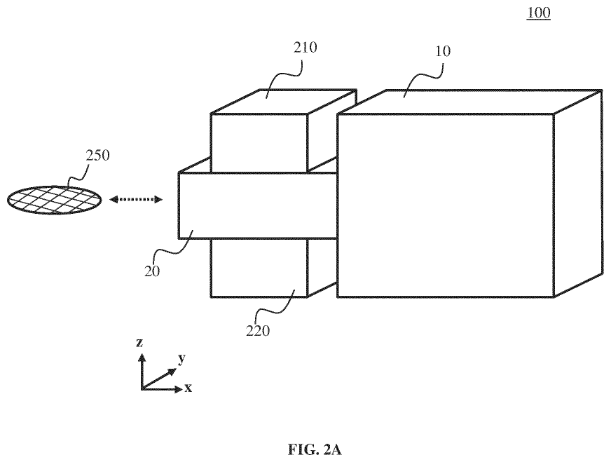

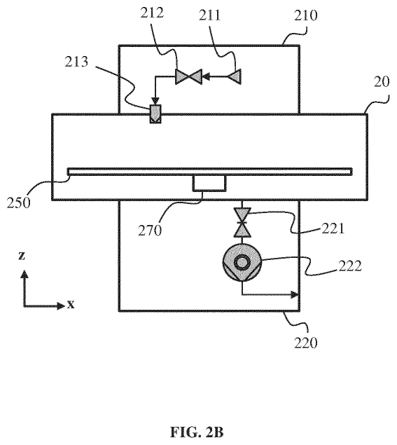

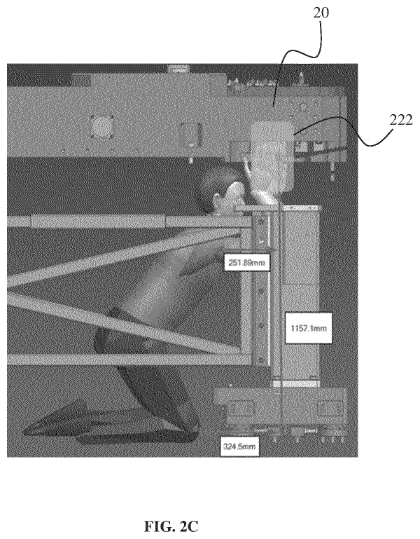

Although FIG. 1A shows that load lock chamber 20 is located within main chamber 10, it is further appreciated that load lock chamber 20 may be located next to main chamber 10 abutting against the outside of the main chamber as shown in FIG. 2A.

Load lock chamber 20 may be attached to main chamber 10 with a gate valve (e.g., gate valve 26 of FIG. 1B) between the chambers. Load lock chamber 20 may include a sample holder (not shown) that can hold one or more wafers. Load lock chamber 20 may also include a mechanical transfer apparatus (e.g., robot arm 12 of FIG. 1B) to move wafers to and from main chamber 10. Load lock chamber 20 may be connected to a load lock vacuum pump system (not shown), which removes gas molecules in load lock chamber 20 to reach a first pressure below the atmospheric pressure. After reaching the first pressure, one or more robot arms (shown in FIG. 1B) transport the wafer from load lock chamber 20 to main chamber 10. Main chamber 10 is connected to a main chamber vacuum pump system (not shown), which removes gas molecules in main chamber 10 to reach a second pressure corresponding to a deeper vacuum state than the first pressure. After reaching the second pressure, the wafer is subject to inspection by electron beam tool 40.

A controller 50 is electronically connected to electron beam tool 40. Controller 50 may be a computer configured to execute various controls of charged particle beam inspection system 100. While controller 50 is shown in FIG. 1A as being outside of the structure that includes main chamber 10, load lock chamber 20, and EFEM 30, it is appreciated that controller 50 may be part of the structure. While the present disclosure provides examples of main chamber 10 housing an electron beam inspection tool, it should be noted that aspects of the disclosure in their broadest sense are not limited to a chamber housing an electron beam inspection tool. Rather, it is appreciated that the foregoing principles may also be applied to other tools that operate under the second pressure.

Reference is now made to FIG. 1B, which is a schematic diagram illustrating an exemplary wafer loading sequence in charged particle beam inspection system 100 of FIG. 1A, consistent with embodiments of the present disclosure. FIG. 1B is a two-dimensional view from the top of inspection system 100. The X and Y axes represent two perpendicular directions defining the projection plane. In some embodiments, charged particle beam inspection system 100 may include a robot arm 11 located in EFEM 30 and a robot arm 12 located in main chamber 10. In some embodiments, EFEM 30 may also include a pre-aligner 60 configured to position a wafer accurately before transporting the wafer to load lock chamber 20.

In some embodiments, first loading port 30a and second loading port 30b, for example, may receive wafer front opening unified pods (FOUPs) that contain wafers. Robot arm 11 in EFEM 30 may transport the wafers from any of the loading ports to pre-aligner 60 for assisting with the positioning. Pre-aligner 60 may use mechanical or optical aligning methods to position the wafers. After pre-alignment, robot arm 11 may transport the wafers to load lock chamber 20.

After the wafers are transported to load lock chamber 20, a load lock vacuum pump (not shown) may remove gas molecules in load lock chamber 20 to reach a first pressure below the atmospheric pressure. After reaching the first pressure, a robot arm 12 may transport the wafer from load lock chamber 20 to a wafer stage 80 of electron beam tool 40 in main chamber 10. Main chamber 10 is connected to a main chamber vacuum pump system (not shown), which may further remove gas molecules in main chamber 10 to reach a second pressure below the first pressure. After reaching the second pressure, the wafer may be subject to inspection by electron beam tool.

In some embodiments, main chamber 10 may include a parking station 70 configured to temporarily store a wafer before inspection. For example, when the inspection of a first wafer is completed, the first wafer may be unloaded from wafer stage 80, and then a robot arm 12 may transport a second wafer from parking station 70 to wafer stage 80. Afterwards, robot arm 12 may transport a third wafer from load lock chamber 20 to parking station 70 to store the third wafer temporarily until the inspection for the second wafer is finished.

Reference is now made to FIG. 2A, which is a schematic diagram illustrating an exemplary charged particle beam inspection system with a conventional load lock chamber. FIG. 2A is a three-dimensional projection view of inspection system 100. The vertical axis (Z-axis) represents the height from the ground. Inspection system 100 includes a load lock chamber 20, which is attached to a main chamber 10. Load lock chamber is used to transfer wafer 250 between the atmospheric cleanroom environment and main chamber 10, which is maintained in a deep vacuum state. Load lock chamber 20 may be connected to pump-down structures 220, which removes gas molecules in load lock chamber 20 to reach a vacuum state. Pump-down structures 220 may include various vacuum pumps, such as a roughing pump and a turbomolecular pump (TMP). Pump-down structures 220 may also include vacuum qualifying tools, such as a plasma cleaner and a residual gas analyzer (RGA). Load lock chamber 20 may also be connected to venting structures 210 configured to inject gas into load lock chamber 20 to restore pressure within load lock chamber to the atmospheric pressure level. In a typical conventional particle beam inspection system, venting structures 210 are installed on top of load lock chamber 20, and pump-down structures 220 are installed under load lock chamber 20.

Reference is now made to FIG. 2B, which is a schematic diagram illustrating an exemplary charged particle beam inspection system with a conventional load lock chamber. As explained above, in a conventional particle beam inspection system, venting structures 210 are installed on top of load lock chamber 20. Venting structures 210 may include a gas supply 211, a gas vent valve 212, and a gas vent port 213. Gas vent port 213 may be placed on the top seal of load lock chamber 20 and configured to inject gas into load lock chamber 20 from top to bottom. Injecting gas from the top of load lock chamber provides a strong downward gas venting flow within load lock chamber 20, which enables fast venting-up operation for better system throughput. The downward gas venting flow further reduces the chance of uninvited particle contamination as it suppresses resuspension of particles, which may be present at the bottom surface of load lock chamber 20.

Similarly, in a conventional particle beam inspection system, pump-down structures 220 are installed under load lock chamber 20. Pump-down structures 220 may comprise a load lock valve 221 and a load lock turbomolecular pump 222. Pump-down structures 220 may also include a load lock roughing valve and a load lock roughing pump (not shown). Pump-down structures 220 may also include vacuum qualifying tools, such as a plasma cleaner and a residual gas analyzer (not shown). Pump-down structures 220, such as vacuum pumps and vacuum qualifying tools, are typically complex, heavy, and relatively prone to fail, therefore demanding more frequent hands-on maintenance work by working personnel. For example, in practice, a turbomolecular pump is known for requiring high level of effort for the installation and maintenance. However, the space underneath of load lock chamber 20 is usually very tight, which poses various problems for working personnel (e.g., an operator, a technician) who need to perform frequent maintenance works in the tight space. For example, FIG. 2C illustrates a technician performing a maintenance work on turbomolecular pump 222 in the tight space under load lock chamber 20. This creates ergonomic problems and even physical dangers for the technician. There is also a higher chance of possible component damages due to improper handling in the congested space with uncomfortable postures.

Simply swapping the positions of venting structures 210 and pump-down structures 220 is not sufficient to solve the forementioned problems. The internal structure of conventional load lock chamber assumes the downward gas venting flow, and accordingly moving the gas vent port (such as gas vent port 213 in FIG. 2B) to the bottom of load lock chamber 20 would result in detrimental flow-induced disturbances, such as wafer dislodging, due to the upward gas flow directly hitting the wafer. Furthermore, as described above, the downward gas flow is usually preferred for its characteristics of suppressing particle resuspension and contamination. In addition, if the gas vent port is placed on the bottom of the load lock chamber, the upward venting flow could stir up particles present within the load lock chamber, and thus resulting in contamination issues.

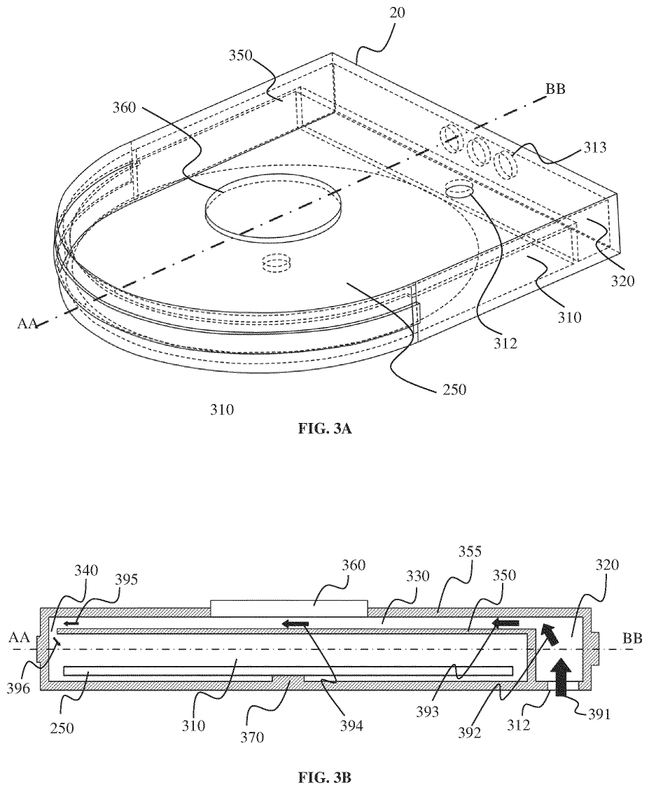

Reference is now made to FIGS. 3A and 3B, which are schematic diagrams illustrating an exemplary load lock chamber, consistent with embodiments of the present disclosure. In some embodiments, load lock chamber 20 may include multiple internal compartments. One side of the load lock chamber 20 may be configured to hold a wafer, and the other side of the load lock chamber is partitioned from the compartment where the wafer is held by an internal structure covering the wafer underneath. This separation can prevent the gas venting flow from directly striking the wafer, even if the gas vent port is located on the bottom of the load lock chamber. For example, as shown in FIGS. 3A and 3B, load lock chamber 20 may include a first compartment 310 and a second compartment 320. First compartment 310 may be configured to receive a wafer 250 for transferring it to and from the main chamber (not shown). During the pump-down and venting operations, wafer 250 is placed on a wafer holder 370. Second compartment 320 may include a gas vent port 312 on the bottom wall of load lock chamber 20. The location of the gas vent port is flexible. For example, instead of gas vent port 312 on the bottom wall, load lock chamber 20 may have one or more side gas vent port 313. In some embodiment, gas vent port 312 and side gas vent port 313 may coexist.

First compartment 310 and second compartment 320 may be partitioned by a flow baffle 350. In some embodiment, flow baffle 350 may have a cantilever shape. Flow baffle 350 may be configured to cover wafer 250 underneath to prevent a direct impact from the vented gas. In some embodiment, second compartment 320 may be smaller than first compartment 310. In some embodiment, flow baffle 350 and a top seal 355 (e.g., the top wall of load lock chamber) may form a flow attenuation path 330, which connects first compartment 310 and second compartment 320. Flow attenuation path 330 enables the vented gas in second compartment 320 to flow to first compartment 310. As indicated by a series of arrows (391-396) in FIG. 3B, for example, during the venting operation, the gas is first injected into second compartment 320 via gas vent port 312, and then flows upward within second compartment 320, and then flows through flow attenuation path 330 across the entire flow baffle, and then finally enters first compartment 310, where wafer 250 is held, via an opening 340. It is appreciated that opening 340 could have various shapes as long as it permits the gas flow into first compartment 310. For example, opening 340 may be a slit formed between an end of flow baffle 350 and an interior surface of a side wall of load lock chamber 20. In some embodiment, opening 340 may be one or more holes placed on flow baffle 350 along the side wall of load lock chamber 20.

The size of arrows 391-396 in FIG. 3B illustrates the gas flow speed attenuation. For example, as shown in FIG. 3B, the gas flow speed is high when the gas enters second compartment 320 (see arrow 391 and 392). However, this high-speed vented gas travels across the majority of load lock chamber through flow attenuation path 330 (see arrow 393, 394, 395). When the gas reaches wafer 250 in first compartment 310 (see arrow 396), the speed of gas flow is greatly reduced. In some embodiment, the amount of speed reduction is greater than 95% relative to the initial speed when the gas is vented into second compartment. In addition, relative to wafer 250, the gas still flows downward within first compartment 310. The combination of slow speed and downward direction reduces the chance of flow disturbances around wafer 250 and particle resuspension, resulting in better protection of wafer 250 and less particle contamination.

Furthermore, it is observed that the magnitude of surface shear velocity (Ustar) on the surface of wafer 250 is low in the improved load lock chamber. The lower surface shear velocity correlates to the lower probability of particle deposition. Accordingly, the low Ustar value on the surface of wafer 250 means that the chance of particle deposition on the surface of wafer 250 in first compartment 310 is low. Therefore, even if some particles are carried into first compartment 310 with the gas venting flow, they are not likely to be deposited onto the surface of wafer 250. In addition, the Ustar value is much greater within flow attenuation path 330 (e.g., on the top surface of flow baffle 350 and/or the lower surface of top seal 355), and thus any particles in the gas venting flow are much more likely to be retained in flow attenuation path 330 instead of reaching wafer 250. The flow attenuation path 330 may effectively function as a particle filter.

In some embodiment, load lock chamber 20 may further include a vacuum port 360, which may be connected to a vacuum pump (e.g., turbomolecular pump or roughing pump) for the pump-down operation. As the gas vent ports (e.g., gas vent port 312 and side gas vent port 313) and the associated venting structures (like venting structures 210 in FIG. 2A) are no longer placed on top of load lock chamber 20, the pump-down structures (like pump-down structure 220 in FIG. 2A) may be installed above load lock chamber 20. This provides better accessibility to the pump-down structures, like a turbomolecular pump or other vacuum qualifying tools for working personnel performing installation or maintenance works. Accordingly, the improved load lock chamber provides better accessibility to high-maintenance-demanding components, like pump-down structure, while still providing the desired downward gas venting flow for better protection of the wafer and less particle contamination.

The embodiments may further be described using the following clauses:

1. A load lock assembly comprising:
a load lock chamber with a gas vent port on a side or bottom of the load lock chamber;
the load lock chamber having a first compartment and a second compartment, the first compartment being configured to receive a wafer for loading into and unloading from a main vacuum chamber and the second compartment being configured to receive gas from the gas vent port and to route the gas to a flow attenuation path that is configured to attenuate gas flow;
wherein the flow attenuation path is further configured to cause the gas that passes through the flow attenuation path to enter the first compartment such that the gas flows downward towards the bottom of the first compartment.
   2. The load lock chamber of clause 1, wherein the flow attenuation path is located above the first compartment.
   3. The load lock chamber of clauses 1-2, further comprising a flow baffle that partitions the flow attenuation path from the first compartment.
   4. The load lock chamber of clause 3, wherein the flow baffle covers a section of the first compartment where the wafer is configured to be placed.
   5. The load lock chamber of clauses 3-4, wherein the flow baffle is a cantilevered structure.
   6. The load lock chamber of clauses 3-5, wherein the flow baffle partitions the first compartment from the second compartment.
   7. The load lock chamber of clauses 1-6, further comprising an opening, near the top of the first compartment, configured to allow the gas to flow from the flow attenuation path into the first compartment.
   8. The load lock chamber of clause 7, wherein the opening is located near a side of the load lock chamber located opposite to the second compartment.
   9. The load lock chamber of clauses 7-8, wherein the opening is a slit-shape.
   10. The load lock chamber of clauses 1-9, wherein the flow attenuation path is configured to cause a top-to-bottom gas flow within the first compartment.
   11. The load lock chamber of clauses 1-10, wherein the height of the flow attenuation path is smaller than the height of the first compartment.
   12. The load lock chamber of clauses 1-11, wherein the volume of the first compartment is larger than the volume of the second compartment.
   13. A load lock chamber, comprising:
a gas vent port;
a first compartment configured to receive a wafer for loading into and unloading from a main vacuum chamber;
a second compartment partitioned from the first compartment, the second compartment configured to receive gas through the gas vent port; and
a flow attenuation path connecting the first compartment and the second compartment, the flow attenuation path configured to route the gas from the second compartment to the first compartment and to attenuate gas flow.
   14. The load lock chamber of clause 13, wherein the gas vent port is positioned on a bottom wall of the load lock chamber.
   15. The load lock chamber of clause 13, wherein the gas vent port is positioned on a side wall of the load lock chamber.
   16. The load lock chamber of clauses 13-15, wherein the flow attenuation path is located above the first compartment.
   17. The load lock chamber of clauses 13-16, further comprising a flow baffle that partitions the flow attenuation path from the first compartment.
   18. The load lock chamber of clauses 17, wherein the flow baffle covers a section of the first compartment where the wafer is configured to be placed.
   19. The load lock chamber of clauses 17-18, wherein the flow baffle is a cantilevered structure.
   20. The load lock chamber of clauses 17-19, wherein the flow baffle partitions the first compartment from the second compartment.
   21. The load lock chamber of clauses 17-20, further comprising an opening, near the top of the first compartment, configured to allow the gas to flow from the flow attenuation path into the first compartment.
   22. The load lock chamber of clause 21, wherein the opening is located near a side of the load lock chamber located opposite to the second compartment.
   23. The load lock chamber of clauses 21-22, wherein the opening is a slit-shape.
   24. The load lock chamber of clauses 13-23, wherein the flow attenuation path causes a top-to-bottom gas flow within the first compartment.
   25. The load lock chamber of clauses 13-24, wherein the height of the flow attenuation path is smaller than the height of the first compartment.
   26. The load lock chamber of clauses 13-25, wherein the volume of the first compartment is larger than the volume of the second compartment.
   27. A load lock assembly, comprising:
a load lock chamber, comprising:
a gas vent port;
a first compartment configured to receive a wafer for loading into and unloading from a main vacuum chamber;
a second compartment partitioned from the first compartment, the second compartment configured to receive gas through the gas vent port; and
a flow attenuation path connecting the first compartment and the second compartment, the flow attenuation path configured to route the gas from the second compartment to the first compartment and to attenuate gas flow;
a vacuum pump connected to the load lock chamber, and a gas supply connected to the load lock chamber through the gas vent port.
   28. The load lock assembly of clause 27, wherein the gas vent port is positioned on a bottom wall of the load lock chamber.
   29. The load lock assembly of clause 27, wherein the gas vent port is positioned on a side wall of the load lock chamber.
   30. The load lock assembly of clauses 27-29, wherein the load lock chamber further comprises a vacuum port positioned on a top wall of the load lock chamber.
   31. The load lock assembly of clauses 27-30, wherein the vacuum pump is located above the load lock chamber.
   32. The load lock assembly of clauses 27-31, wherein the vacuum pump comprises a roughing pump or a turbomolecular pump.

Although the disclosed embodiments have been explained in relation to its preferred embodiments, it is to be understood that other modifications and variation can be made without departing the spirit and scope of the subject matter as hereafter claimed.

1. A load lock chamber, comprising:
a gas vent port;
a first compartment configured to receive a wafer for loading into and unloading from a main vacuum chamber;
a second compartment partitioned from the first compartment, the second compartment configured to receive gas through the gas vent port; and
a flow attenuation path connecting the first compartment and the second compartment, the flow attenuation path configured to route the gas from the second compartment to the first compartment and to attenuate gas flow.

2. The load lock chamber of claim 1, wherein the gas vent port is positioned on a bottom wall of the load lock chamber.

3. The load lock chamber of claim 1, wherein the gas vent port is positioned on a side wall of the load lock chamber.

4. The load lock chamber of claim 1, wherein the flow attenuation path is located above the first compartment.

5. The load lock chamber of claim 1, further comprising a flow baffle that partitions the flow attenuation path from the first compartment.

6. The load lock chamber of claim 5, wherein the flow baffle covers a section of the first compartment where the wafer is configured to be placed.

7. The load lock chamber of claim 5, wherein the flow baffle is a cantilevered structure.

8. The load lock chamber of claim 5, wherein the flow baffle partitions the first compartment from the second compartment.

9. The load lock chamber of claim 5, further comprising an opening, near the top of the first compartment, configured to allow the gas to flow from the flow attenuation path into the first compartment.

10. The load lock chamber of claim 9, wherein the opening is located near a side of the load lock chamber located opposite to the second compartment.

11. The load lock chamber of claim 9, wherein the opening is a slit-shape.

12. The load lock chamber of claim 1, wherein the flow attenuation path causes a top-to-bottom gas flow within the first compartment.

13. The load lock chamber of claim 1, wherein the height of the flow attenuation path is smaller than the height of the first compartment.

14. The load lock chamber of claim 1, wherein the volume of the first compartment is larger than the volume of the second compartment.

15. A load lock assembly, comprising:
a load lock chamber, comprising:
a gas vent port;
a first compartment configured to receive a wafer for loading into and unloading from a main vacuum chamber;
a second compartment partitioned from the first compartment, the second compartment configured to receive gas through the gas vent port; and
a flow attenuation path connecting the first compartment and the second compartment, the flow attenuation path configured to route the gas from the second compartment to the first compartment and to attenuate gas flow;
a vacuum pump connected to the load lock chamber, and
a gas supply connected to the load lock chamber through the gas vent port.

16. The load lock assembly of claim 15, wherein the gas vent port is positioned on a bottom wall of the load lock chamber.

17. The load lock assembly of claim 15, wherein the gas vent port is positioned on a side wall of the load lock chamber.

18. The load lock assembly of claim 15, wherein the load lock chamber further comprises a vacuum port positioned on a top wall of the load lock chamber.

19. The load lock assembly of claim 15, wherein the vacuum pump is located above the load lock chamber.

20. The load lock assembly of claim 15, wherein the vacuum pump comprises a roughing pump or a turbomolecular pump.
